(19) United States
(12) Patent Application Publication
(10) Pub. No.: US 2001/0023756 A1
(43) Pub. Date: Sep. 27, 2001

(54) Assembled structure having an enlarged heat transfer area for heat radiation therefrom

(76) Inventors: Naoto Tanaka, Nagano-ken (JP); Katsuyuki Moritsugi, Nagano-ken (JP)

Correspondence Address: STAAS & HALSEY LLP, 700 11TH STREET, NW, SUITE 500, WASHINGTON, DC, 20001, US

(21) Appl. No.: 09/781,191

(22) Filed: Feb. 13, 2001

Related U.S. Application Data
(63) Continuation-in-part of application No. 08/977,722, filed on Nov. 25, 1997, now Pat. No. 6,202,738.

(30) Foreign Application Priority Data
Dec. 3, 1996 (JP) 322992/1996

(51) Int. Cl. F28F 7/00; H05K 7/20

(52) U.S. Cl. 165/80.3; 165/185; 361/704

(57) ABSTRACT

This invention is related to an assembled structure of laminate plates for radiating heat therefrom wherein there are formed a plurality of slits between peripheries of the plates around the laminated assembly in such a manner that the plurality of laminated plates, each having a length and a shorter width and notches at the edge on the center line of the direction of the length, and each being laminated alternatively with an adjacent abutting plate such that the length of one plate is perpendicular to the width of the adjacent plate to form a shape of a cross, with the excess length of one plate overhanging beyond the width of an adjacent plate, the overhanging portions serving to dissipate heat from the plates.

### BACKGROUND OF THE INVENTION

1. Field of the Invention

The invention is related to an assembled structure of a plurality of laminated plates, in particular, a structure wherein the outer surface is enlarged for promotion of heat radiation therefrom.

2. Description of the Prior Art

In electronic parts having any current circuits other than super-conducting circuits, an electric current flowing therein generates inevitably heat more or less.

The heat is radiated into an atmosphere surrounding the electronic parts.

If quantity of heat generated in electric circuits exceeds what is removed therefrom, the electric parts accumulates heat therein and naturally increase their own temperature.

An excessive temperature increase of the electronic parts brings finally the device to thermal destruction.

As a measure of avoiding such a problem, it is conventionally used to enlarge dimensions of the electric parts to thereby increase the outer surface and its heat capacity sufficiently. This realizes an appropriate heat balance between generation and radiation of heat to restrain its temperature increase.

If it is impossible to employ such a technique as to increase sufficiently the outer surface and heat capacity of the parts, the following conventional methods are used.

For instance, there is formed a heat sink to be connected to such an electric device as a power transistor and to radiate heat of the transistor. Another method is to blow an air by use of fan onto a targeted device surface to remove forcibly heat therefrom.

An electric rotary machine, like a stepping motor and so on, has cores of soft magnetic material around which coils are wound, and is rotated by magnetic flux passing through the cores which is caused by an electric current flowing in windings of the coils.

An electric current flowing in a wound coil causes some quantity of heat therein. At the same time it generates magnetic flux to go through the core and also causes some heat therein because of magnetic resistance of the core.

The heat brought by magnetic flux is radiated from a surface of the core into an atmosphere . This core is conventionally made of a plurality of laminate sheets each of which is resulted from punching an original magnetic sheet.

It is further explained below about parts of a magnetic rotary machine obtained by laminating a plurality of punched magnetic sheets.

The punched magnetic sheets, each of which is shown in FIG. 5, are laminated in congruency with each other to form a laminated body 51 for the parts as illustrated in FIG. 6 (it illustrates an example of a stator core of a stepping motor). Thus, a stepping motor is obtained as shown in FIG. 7.

In FIG. 7, the donations of 52, 53 and 54 represent a rotary shaft, a magnet secured to the rotary shaft 52 and a coil wound around the laminated body 51 (a stator core). Heat generated inside the stepping motor is radiated from the surface thereof toward a surrounding atmosphere. However, in case that such radiation is insufficient for cooling, it is necessary to adopt any of the following measures of enlarging dimensions of a stepping motor, connecting a heat source to a heat sink outside, and blowing an air onto an outer surface of a stepping motor to forcibly radiate heat toward the surrounding air.

In design of a transformer having a core of magnetic laminate sheets, the core needs to be provided with a minimum essential of cross-sectional area through which the necessary magnetic flux must passes depending upon the design requirement. However, as a result of designing a small size transformer according to such a manner, it reaches such a problem that a temperature of the magnetic core is gradually increased because of insufficient heat radiation therefrom.

To avoid the problem, a conventional method is to make a size of a magnetic core larger than that to be required in view of the design method mentioned above.

On the other hand, there is a demand for reducing an outer size of a magnetic core to be as small as possible because recently it is valued to make an electric apparatus small and compact.

In the electric assemblies like electronic parts, electric rotary machines and transformers mentioned above, there appear the next problems. That is, if heat generated in the assembly is handled to be removed by natural radiation, the assembly naturally becomes large in size. In using a heat sink for radiation, it requires a lot of metalworking steps including where a molding metal body with fins for a heat sink is subjected to any cutting process to form a plain surface thereon for connection with the assembly. Moreover, such a heat sink is expensive because of increase of the manufacturing steps and also makes the resultant assembly large in size. If a heat sink is provided with an air blowing means like a cooling fan, the resultant product becomes large and expensive after all.

### SUMMARY OF THE INVENTION

This invention is directed toward solving the above problems in the prior arts.

The object of the invention is to provide a laminated assembly having a simple structure for heat radiation. In detail, this invention is to provide a laminated assembly with a accurate positioning having an enlarged outer surface so that heat radiation therefrom is promoted when it is either integrally fixed or attached to electric parts causing heat.

For the purposes of the invention, the present invention provide an assembled structure of a plurality of laminated plates having high thermal conductivity, the assembled structure comprising, a plurality of laminated plates, each having with a circular opening at the center of the plate, a plurality of projection parts extend from an outer periphery of the plate toward the circular opening for forming stator magnetic poles, the plurality of laminated plates, each having a length and a shorter width and notches at the edge on the center line of the direction of the length, and each being laminated alternatively with an adjacent abutting plate such that the length of one plate is perpendicular to the width of the adjacent plate to form a shape of a cross, with the excess length of one plate overhanging beyond the width of an adjacent plate, the overhanging portions serving to dissipate heat from the plates.

### BRIEF DESCRIPTION OF THE DRAWINGS

FIG. 1 is a plain view of a magnetic sheet used in an embodiment of the invention.

FIG. 2 is a perspective view showing a laminated assembly of magnetic sheets in an embodiment of the invention.

FIG. 3 is a side view of the laminated assembly in FIG. 2.

FIG. 4 is a side view of an laminated assembly of an embodiment of the invention.

FIG. 5 is a plain view of a magnetic sheet for a magnetic core of a stepping motor in prior art.

FIG. 6 is a perspective view of a laminated assembly used as a magnetic core of a stepping motor in prior art.

FIG. 7 is a cross sectional view of a stepping motor in prior art.

### DESCRIPTION OF THE PREFERRED EMBODIMENTS

Exemplary embodiments of the invention will be now described in conjunction with the accompanying drawings. It is shown about an embodiment in which this invention is applied to an assembly of a stator core in a stepping motor. FIG. 1 is a plain view of a magnetic sheet for a stator core. There is provided with a circular opening 2 at the center of the sheet 1 for accommodating a rotator magnet. A plurality of projection parts extend from an outer periphery 3 of the sheet I toward the circular opening 2 for forming stator magnetic poles 4. These projection parts are positioned at even central angle 90/N [degree] (N is an integer) viewed from the center O of the opening 2. In this embodiment, the number N is two (2) and so the central angle is forty-five (45) degrees.

The donations 5 are holes for fixing firmly the laminated assembly 6 laminated with plural sheets 1 and brackets 56 and 57 (showed in Fig.). When the motor was assembled, the holes 5 and holes in the brackets 56 and 57 are penetrated with bolts and the brackets 56, 57 and laminated assembly 6 sandwiched with the brackets are firmly fixed by nuts.

These four fixing holes 5 are placed on the same circle at even intervals of central angles of 90 degrees. This make it possible that one sheet is put on another sheet in such a manner as to turn the alternate sheets round in 90-degree arc because each position of the holes 5 of the turned sheets remain in alignment with those of the other sheets.

The horizontal length H is larger than the vertical length V in the sheet (H>L).

The donation 17 is a positioning notch. The two positioning notches 17 are placed on the traversed H line passing through center point O. Sheets 1 configured above are put on each other and the alternate ones are turned round in 90-degree arc. The gap of 90-degree between sheets 1 are confirmed by the positioning notches 17. A figure of above mentioned positioning notch is a triangle shape, but the figure of the positioning notch is not only a triangle shape, but also a rectangle shape or a semicircular shape, and every positioning notches must be confirmed the gap of 90-degree.

Above mentioned sheet 1 is laminated alternatively with an adjacent abutting plate such that the length of one plate is perpendicular to the width of the adjacent plate to form a shape of a cross, with the excess length of one plate overhanging beyond the width of an adjacent plate, the overhanging portions serving to dissipate heat from the plates.

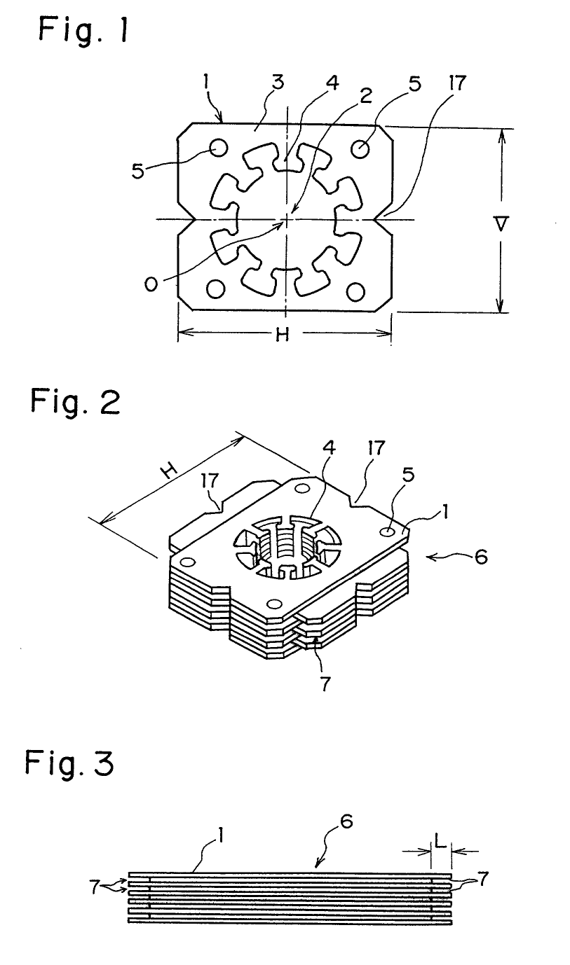

The laminated plural sheets 1 are glued, then laminated and glued sheets are formed the laminated assembly 6 as showed in FIG. 2. Not showed in the drawings but in the above sheet laminating process, the positioning notch 17 is fitted into positioning pins on the jig, therefore, the sheets are laminated with easily and accurately.

Not showed in the drawings but, a fixing frame for gluing the laminated sheet is fitted in the positioning notch 17 in the forming process of laminated assembly 6.

Not showed in the drawings but, coils are directly wound round each stator pole 4 of the laminated assembly 6, which constitutes an element of a stepping motor. In the stepping motor, the first pulse current flows in one pair of the coils and the second current flows in another pair of them. Similarly, by applying subsequently pulse current to the coils, a rotor of the stepping motor is rotated.

A pulse electric current is supplied to each coil through electric circuits outside the motor and the current strength varies in accordance with the load. The temperature increase of the motor is mainly caused by both copper loss in coils and core loss in the laminated assembly. The electric current depending on the rotating power of rotor is supplied from the outside electronic circuit by the pulse current. The pulse current will be changed by the load mass. The heat generated in the coils by the current and in the stator core by the magnetic flux is transferred to the whole of the motor.

On the other hand, as mentioned above, the vertical length V and horizontal length H of the magnetic sheet 1 are different from each other, and each of the magnetic sheets 1 is put on its adjacent sheet in such a manner that the alternative sheets are turned round in 90-degree arc. Accordingly, there are formed a lot of slits 7 along the peripheries of the sheets on the outer surface of the assembly. The depth of the slits 7 is shown as L=(H-V)/2.

Since there are thus formed the slits on the side surface of the laminated assembly of the stator core as shown in FIG. 3, the surface exposed to the surrounding air is enlarged greatly. As a result, it radiates greater amount of heat to the air than any stator core in prior arts.

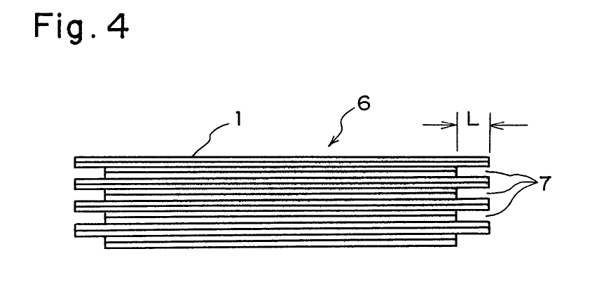

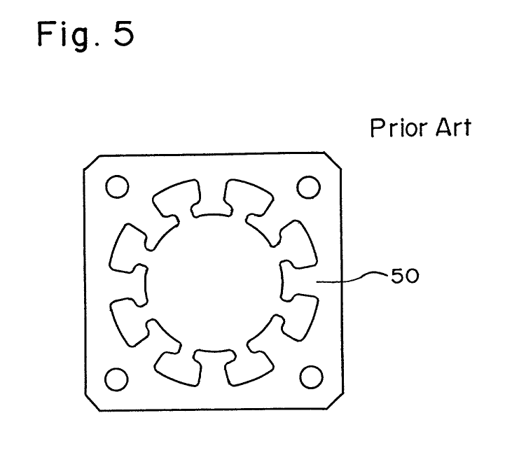

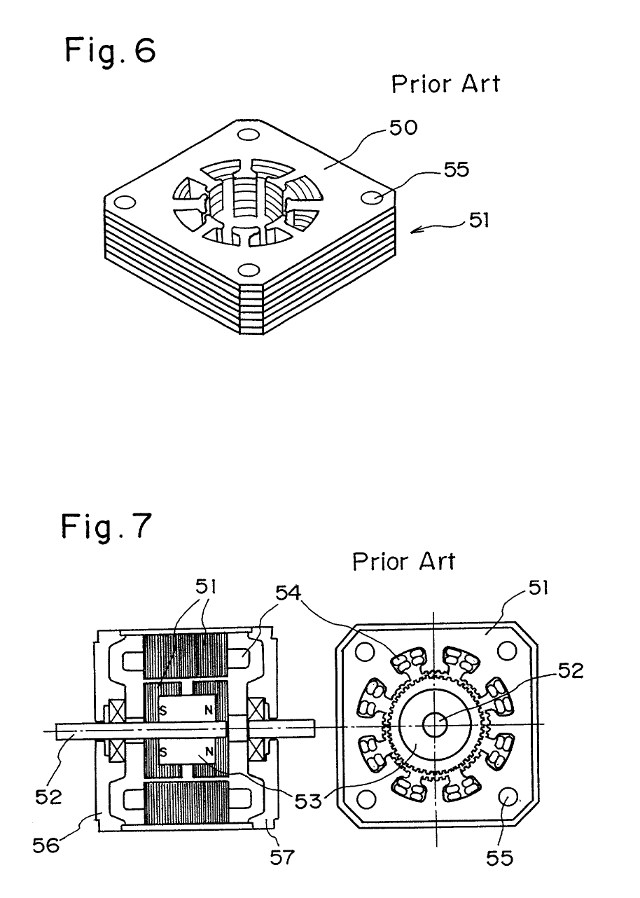

FIG. 4 is a cross section showing the second exemplary embodiment. It uses sheet units each consisting of two adjacent magnetic sheets 1,1 put together congruently. In this case, the alternate sheet units are turned round in 90-degree arc around the center thereof. Though the whole outer surface becomes smaller than that of the first embodiment, the increased width of each slit 7 improves ventilation there-through. In the end, the radiation efficiency almost remains unchanged.

What is claimed is:

1. An assembled structure of a plurality of laminated plates having high thermal conductivity, the assembled structure comprising:
A plurality of laminated plates, each having with a circular opening at the center of the plate,
A plurality of projection parts extend from an outer periphery of the plate toward the circular opening for forming stator magnetic poles,
The plurality of laminated plates, each having a length and a shorter width and notches at the edge on the center line of the direction of the length, and each being laminated alternatively with an adjacent abutting plate such that the length of one plate is perpendicular to the width of the adjacent plate to form a shape of a cross, with the excess length of one plate overhanging beyond the width of an adjacent plate, the overhanging portions serving to dissipate heat from the plates.

2. The assembled structure according to claim 1, wherein the laminated plates are rectangular plates.

3. The assembled structure according to claim 1, wherein each plate is a magnetic sheet and the assembled structure forms a magnetic core.

4. The assembled structure according to claim 3, wherein the magnetic core is applied to a stator core of a rotary electric machine.

5. The assembled structure according to claim 4, wherein the rotary electric machine is a stepping motor.

6. The assembled structure according to claim 1, wherein the notch being a triangle shape.

7. The assembled structure according to claim 1, wherein the notch being a semicircle shape.

8. The assembled structure according to claim 1, wherein the notch being a rectangular shape.
